(19) United States
(12) Patent Application Publication
(10) Pub. No.: US 2011/0267756 A1
(43) Pub. Date: Nov. 3, 2011

(54) WEAR-RESISTANT KEYBOARDS METHODS FOR PRODUCING SAME

(76) Inventors: Charles A. Sellers, Houston, TX (US); Kevin F. Clancy, Spring, TX (US); Philip Kao, Taipei (TW)

(21) Appl. No.: 12/991,483

(22) PCT Filed: May 8, 2008
(86) PCT No.: PCT/US08/62991

§ 371 Date: Jan. 26, 2011

(51) Int. Cl. H05K 7/00; B05D 5/00; B05D 3/06; H01H 13/76

(52) U.S. Cl. 361/679.09; 200/5 A; 427/271; 427/510; 427/555

(57) ABSTRACT

A keyboard for use with a computing device. In some embodiments, the keyboard comprises a plurality of keys having upper surfaces to which a durable protective coating has been applied and legend symbols that have been etched into the upper surfaces through the durable protective coating.

### BACKGROUND

Several computer manufacturers sell computers in multiple countries that comprise various native languages. Although such manufacturers can maintain large inventories of keyboards specific to each of the different languages, it is more preferable to simply maintain an inventory of blank keyboards and apply symbols to the keys as orders from given territories are received. For example, when an order is received from Greece, a number blank keyboards can be sent to a print service provider for application of Greek symbols to the keys. With such a practice, inventories, and therefore costs, can be reduced.

Although the above practice works well for most keyboards, difficulties arise for keyboards to which protective coatings are applied. Such coatings are applied after printing has been performed. Unfortunately, most print service providers will not apply such coatings because of the costs associated with complying with regulations that govern handling of the chemicals involved. Because of this, the manufacturer may need to first send the keyboards to the print service provider for application of the key symbols and then make arrangements for the coating to be applied to the keys. Such a process increases both the delay and costs in producing the computing devices in which the keyboards are to be provided.

### BRIEF DESCRIPTION OF THE DRAWINGS

The disclosed keyboards and methods can be better understood with reference to the following drawings. The components in the drawings are not necessarily to scale.

FIG. 1 is a schematic view depicting apparatus for applying and curing durable protective coating.

FIG. 2 is a schematic view depicting etching of symbols into keys of a keyboard to which a durable protective coating has been applied.

FIG. 3A is a close-up schematic view of a symbol being laser etched into a keyboard key.

FIG. 3B illustrates the keyboard key after the etching of FIG. 3A.

FIG. 4 is a perspective view of an embodiment of a computing device that incorporates the keyboard shown in FIG. 2.

FIG. 5 is a flow chart of an embodiment of a method for producing a computing device keyboard.

### DETAILED DESCRIPTION

As described above, the need to apply a protective coating to keyboard keys can increase delay and cost in the production of computing devices that incorporate the keyboards. As described in the following, however, delays and/or costs can be reduced by etching legend symbols into the keys of the keyboard after the protective coating has been applied. In some embodiments, the symbols are laser etched into the keys.

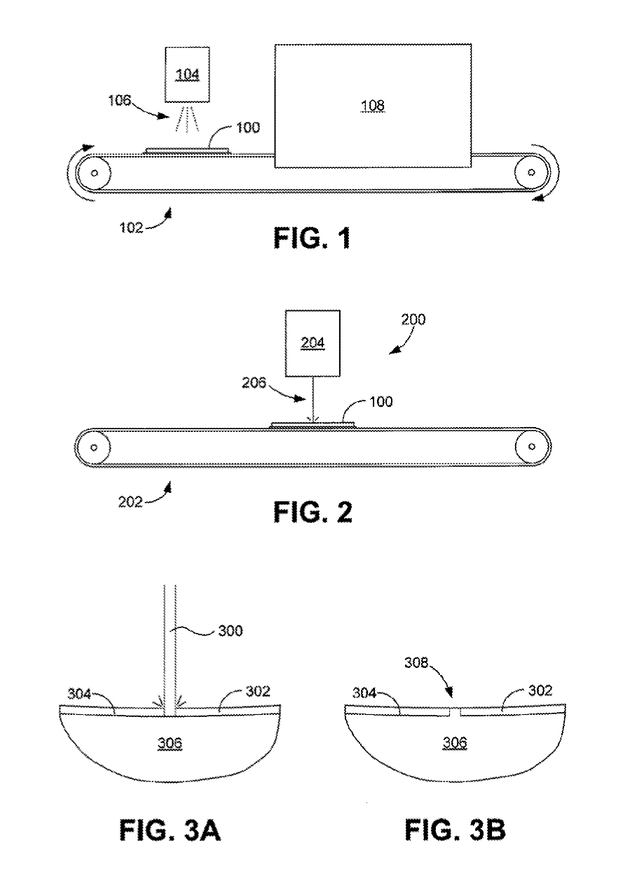

Turning to the figures, in which like numerals identify corresponding components, illustrated in FIG. 1 is a keyboard module 100 of the type that can be provided in a keyboard of a desktop or notebook computer. At this stage, the keys of the keyboard module 100 are blank and contain no legend symbols. As indicated in FIG. 1, the keyboard module 100 is provided on a conveyor 102 that transports the keyboard module to a position adjacent (e.g., below) a spray apparatus 104 that sprays an ultraviolet (UV)-curable polymer 106 onto the keys of the keyboard module 100. After the keys have been coated with the UV-curable polymer 106, the keyboard module 100 can be transported by the conveyor 102 to a UV oven 108 in which the coating can be exposed to UV radiation that cures, and therefore hardens, the coating.

With reference next to FIG. 2, the keyboard module 100 is brought to an etching station 200 after curing has been completed using a further conveyor 202. At the etching station 200, a laser 204 emits a laser beam 206 of the proper frequency and power to penetrate through the cured coating and etch desired symbols in the keys of the keyboard. Such etching is described further in relation to FIGS. 3A and 3B.

Referring now to FIG. 3A, a laser beam 300 that has been emitted by the laser 204 etches through the durable protective coating 302 applied to and cured on the upper surface 304 of a keyboard key 306. In some embodiments, the coating 302 is in the range of approximately 10 microns (μm) to 20 μm thick. For example, the coating 302 can be approximately 15 μm thick. In some embodiments, the key 306 comprises a key cap that is snap fit to a button mechanism of the keyboard module 100. By way of example, the key 306 is constructed of a plastic material, such as acrylonitrile butadiene styrene (ABS) plastic to which a laser-markable compound has been added. In such an embodiment, the key 306 may be said to be formed of laser-markable ABS plastic. In other embodiments, the key 306 comprises no such laser-markable compound.

As shown in FIG. 3A, the laser beam 300 passes through the durable protective coating 302 to the surface 304 of the key 306. Upon contacting the key surface 304, the surface is discolored to provide contrast with the remainder of the surface of the key 306. That contrast enables the user to see the symbols etched upon the key 306 clearly. In some embodiments the symbols are a light color, such as, white, yellow, or yellow-white and the remainder of the key surface 304 is a dark color, such as dark gray or black.

FIG. 3B illustrates the key 306 after laser etching. As indicated in FIG. 3B, substantially no trench or trough results from the etching away of the durable protective coating due to localized expansion 308 of the key material at the point of etching. Because of such expansion 308, the key 306 will be less likely to trap dirt and other contaminants that could obstruct the symbol over time.

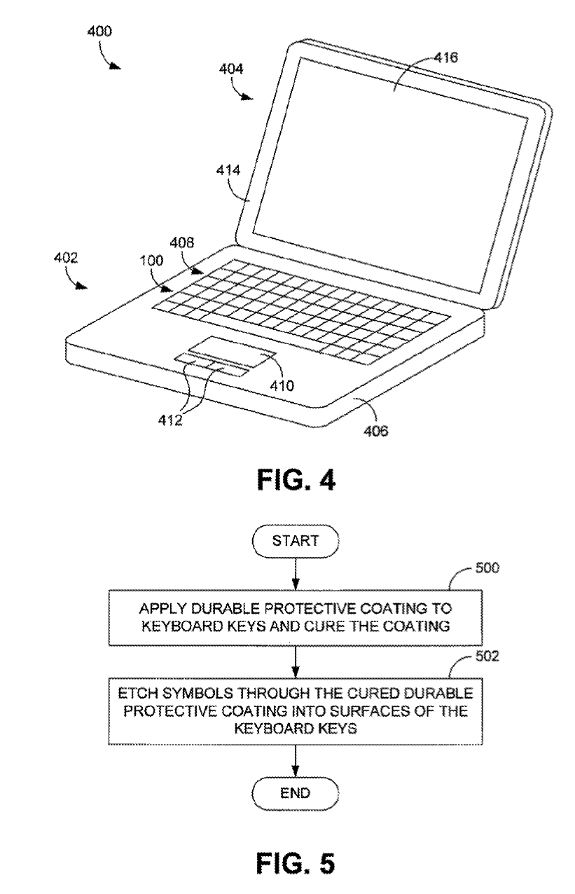

Illustrated in FIG. 4 is an embodiment of a computing device 400 configured as a notebook or “laptop” computer that incorporates the keyboard module 100. The computing device 400 generally comprises a base portion 402 and a display portion 404. The base portion 402 comprises a housing 406 that contains various internal components of the computing device 400, such as one or more processors, memory, a hard drive, and the like. Also comprised by the base portion 402 is a user interface including a keyboard 408 of the keyboard module 100, a touch pad 410, and selection buttons 412. The display portion 404 also comprises a housing 414 that surrounds a display 416, such as a liquid crystal display (LCD).

FIG. 5 is a flow chart that describes actions of an embodiment of producing a computing device keyboard consistent with the above disclosure. Beginning with block 500, a durable protective coating is applied to the keys of a keyboard and cured. Next, symbols are etched through the durable protective coating and into the surfaces of the keyboard keys, as indicated in block 502.

As can be appreciated from the foregoing, blank keyboards that already comprise a durable protective coating can be inventoried and customized to fill orders from multiple countries having different native languages. Accordingly, there is no need to inventory keyboards having legends specific to all territories that the manufacturer serves.

1. A keyboard for use with a computing device, the keyboard comprising:
a plurality of keys having upper surfaces;
a durable protective coating that has been applied to the upper surfaces of the keys; and
legend symbols that have been etched into the upper surfaces of the keys through the durable protective coating.

2. The keyboard of claim 1, wherein the upper surfaces are formed on key caps of the keys.

3. The keyboard of claim 1, wherein the keys are constructed of a plastic material.

4. The keyboard of claim 1, wherein the keys are constructed of acrylonitrile butadiene styrene (ABS) plastic.

5. The keyboard of claim 1, wherein the keys are constructed of acrylonitrile butadiene styrene (ABS) plastic to which a laser-markable compound has been added.

6. The keyboard of claim 1, wherein the upper surfaces of the keys are a dark color.

7. The keyboard of claim 1, wherein the durable protective coating is approximately 10 to 20 microns thick.

8. The keyboard of claim 1, wherein the durable protective coating is approximately 15 microns thick.

9. The keyboard of claim 1, wherein the durable protective coating is an ultraviolet-curable coating.

10. The keyboard of claim 1, wherein the symbols are a light color.

11. The keyboard of claim 1, wherein substantially no trenches exist at the points at which etching has been performed.

12. A computing device comprising:
a keyboard including a plurality of keys having a durable protective coating that has been applied to upper surfaces of the keys and legend symbols that have been etched into the upper surfaces of the keys through the durable protective coating.

13. The computing device of claim 12, wherein the keys are constructed of acrylonitrile butadiene styrene (ABS) plastic to which a laser-markable compound has been added.

14. The computing device of claim 12, wherein the upper surfaces of the keys are a dark color and the symbols are a light color.

15. The computing device of claim 12, wherein the durable protective coating is approximately 10 to 20 microns thick.

16. The computing device of claim 12, wherein the durable protective coating is an ultraviolet-curable coating.

17. The computing device of claim 12, wherein substantially no trenches exist on the keys at the points at which etching has been performed.

18. A method for producing a keyboard, the method comprising:
applying a durable protective coating to blank keys of a keyboard;
curing the durable protective coating; and
etching legend symbols into surfaces of the keys through the cured durable protective coating.

19. The method of claim 18, wherein applying a durable protective coating comprises applying an ultraviolet-curable coating and wherein curing the durable protective coating comprises exposing the durable protective coating to ultraviolet radiation.

20. The method of claim 18, wherein the keys are constructed of a laser-markable plastic and wherein etching comprises etching the legend symbols into the surfaces of the keys using a laser.
